(19) United States
(12) Patent Application Publication
(10) Pub. No.: US 2025/0142826 A1
(43) Pub. Date: May 1, 2025

(54) METHOD FOR MANUFACTURING THREE-DIMENSIONAL NAND FLASH MEMORY ARRAY

(71) Applicants: HPSP Co., Ltd., Hwaseong-si (KR); POSTECH Research and Business Development Foundation, Pohang-si (KR)

(72) Inventor: Hyunsang HWANG, Daegu (KR)

(21) Appl. No.: 19/006,889

(22) Filed: Dec. 31, 2024

Related U.S. Application Data
(63) Continuation of application No. PCT/KR2023/009340, filed on Jul. 3, 2023.

(30) Foreign Application Priority Data
Jul. 1, 2022 (KR) 10-2022-0081456

(51) Int. Cl. H10B 43/27; H10B 41/27

(52) U.S. Cl. CPC H10B 43/27; H10B 41/27

(57) ABSTRACT

According to one embodiment of the present invention, a method for manufacturing a three-dimensional NAND flash memory array may include a polygate forming step of alternately stacking gates and gate insulating on a substrate to form a polygate; an opening forming step of forming an opening in the polygate; a polysilicon forming step of depositing silicon and an oxide filler into the opening to form a polysilicon; a metal film forming step of injecting metal into the polysilicon to form a metal film along a sidewall of the polysilicon; a crystal phase transition and growth step of irradiating a first microwave to the opening to grow crystalline silicon between the metal film and the polysilicon; and a crystal phase expansion step of irradiating a second microwave to the opening to expand the crystalline silicon toward a bottom surface of the opening.

### CROSS-REFERENCE TO RELATED APPLICATION

This application is a Continuation of PCT application No. PCT/KR2023/009340 filed on Jul. 3, 2023, which is based upon and claims the benefit of priority to Korean Patent Application No. 10-2022-0081456 filed on Jul. 1, 2022, in the Korean Intellectual Property Office. All of the aforementioned applications are hereby incorporated by reference in their entireties.

### FIELD

The present disclosure relates to semiconductor technology, and more particularly, to a method for manufacturing a three-dimensional NAND flash memory array.

### DESCRIPTION OF RELATED ART

Due to the development of technologies for mobile devices such as smartphones and tablets and the increase in demand therefor, the demand for a storage device with increased integration is also rapidly increasing. In order to increase the integration of a storage device in a small area, the storage device has also been replaced from a conventional hard disk drive (HDD) to a solid state memory (SSD). In this regard, the demand for a non-volatile memory device among the SSD devices is increasing rapidly. As the non-volatile memory device, a NAND flash memory device with increased integration and reduced cost has been widely commercialized.

A three-dimensional NAND flash memory device is manufactured by vertically stacking cells as basic storage units. In this case, as the number of stacked layers increases, bit density may be improved and cost per bit may be reduced.

Currently, more than 100 layers are stacked in the 3D NAND flash memory device. Due to the continuous increase in capacity, it is expected to expand the number of stacked layers to at least four digit number.

In addition, in the 3D NAND flash memory device, polysilicon is used as a channel material, thereby reducing the cost.

When the channel is made of polysilicon, resistance increases in a read operation, and thus a read current in a cell is smaller than a minimum current level that can be sensed by a sensing circuit, thereby causing difficulty in the read operation. Further, when the number of stacked layers is high, there is a problem in that electric field mobility in the channel is relatively lowered.

The limitation of the polysilicon is an obstacle that limits the long-term expansion of the three-dimensional NAND flash memory device.

Crystallization techniques are used to improve device characteristics of such amorphous polysilicon. The crystallization technique includes SPC (solid phase crystallization), which recrystallizes the polysilicon by increasing the temperature to a value above the melting point of silicon, ELC (excimer laser crystallization) which targets only amorphous polysilicon to crystallize a local area, and MILC (metal induced lateral crystallization) which crystallizes the polysilicon at a low temperature.

The solid phase crystallization (SPC) is performed at high temperature, and thus has difficulty in terms of the process. The excimer laser crystallization (ELC) can crystallize the polysilicon in a local area, so that there are few process constraints. However, there are problems such as having to prepare laser equipment, thus causing an increase in cost, and low yield of crystallized polysilicon.

In the amorphous polysilicon crystallization using the metal-induced lateral crystallization (MILC), the polysilicon is formed, and metal is injected thereto to achieve growth of NiSi₂ crystals, and then, NiSi₂ expansion is performed.

Korean Patent Application Publication No. 10-2021-0117522 (Publication Date: 2021 Sep. 29) discloses a first semiconductor pattern crystallized by the above-described metal-induced lateral crystallization (MILC). However, the metal-induced lateral crystallization (MILC) also requires a long process time, and has a high heat load as the process proceeds at a high temperature.

### DISCLOSURE

### Technical Purposes

A purpose of the present disclosure is to provide a method for manufacturing a three-dimensional NAND flash memory array capable of minimizing a reduction in read current even when the number of cells is increased to improve the integration.

### Technical Solutions

In order to achieve the above technical purpose, the present disclosure provides a method for manufacturing a three-dimensional NAND flash memory array.

According to an embodiment of the present disclosure, a method for manufacturing a three-dimensional NAND flash memory array may include a polygate forming step of alternately stacking gates and gate insulating on a substrate to form a polygate; an opening forming step of forming an opening in the polygate; a polysilicon forming step of depositing silicon and an oxide filler into the opening to form a polysilicon; a metal film forming step of injecting metal into the polysilicon to form a metal film along a sidewall of the polysilicon; a crystal phase transition and growth step of irradiating a first microwave to the opening to grow crystalline silicon between the metal film and the polysilicon; and a crystal phase expansion step of irradiating a second microwave to the opening to expand the crystalline silicon toward a bottom surface of the opening.

According to an embodiment, the method for manufacturing the three-dimensional NAND flash memory array may further include a polysilicon pretreatment step of irradiating a third microwave to the opening to pretreat the polysilicon before the metal film forming step.

According to an embodiment, the method for manufacturing the three-dimensional NAND flash memory array may further include a defect removal step of performing an annealing process in a hydrogen atmosphere to remove a defect on the crystalline silicon after the crystal phase expansion step.

According to an embodiment, the defect removal step may be performed in a pressure range of 2 atmospheres to 50 atmospheres.

According to an embodiment, the defect removal step may be performed in a temperature range of 200° C. to 800° C.

According to an embodiment, the first microwave may be output in a range of 1 KW to 10 KW.

According to an embodiment, the first microwave may be irradiated in a frequency band range of 2.4 GHz to 2.5 GHz.

According to an embodiment, the crystal phase transition and growth step may be performed in a temperature range of 200° C. to 600° C.

The metal may be any one selected from nickel (Ni), titanium (Ti), molybdenum (Mo), cobalt (Co), and aluminum (Al).

### Technical Effects

According to an embodiment of the present disclosure, since the metal induced lateral crystallization (MILC) is performed at a relatively low temperature based on a combination of microwave annealing and hydrogen annealing, there is an advantage in that the heat load is lowered in the manufacturing process of the three-dimensional NAND flash memory array.

According to an embodiment of the present disclosure, there is an advantage in that a reduction in the read current of a three-dimensional NAND flash memory array is minimized by performing the metal induced lateral crystallization (MILC) at a relatively low temperature based on the combination of microwave annealing and hydrogen annealing.

According to another embodiment of the present disclosure, in the crystal phase transition and growth step, the first microwaves are irradiated to the metal film to induce the ohmic conduction absorption of the metal so that the metal atoms rapidly penetrate the interface of the polysilicon, thereby reducing the manufacturing process time of the three- dimensional NAND flash memory array.

According to still another embodiment of the present disclosure, there is an advantage in that the manufacturing process time of the three-dimensional NAND flash memory array is shortened by providing kinetic energy resulting from the irradiating of the second microwave to the vertical NAND channel to rapidly expand the crystalline silicon to the bottom surface of the vertical NAND channel in the crystal phase expansion step.

According to still another embodiment of the present disclosure, the polysilicon is pretreated by irradiating the third microwave to the polysilicon in the polysilicon pretreatment step, thereby removing impurities in the polysilicon and improving the binding stability of the metal film to be formed on the interface of the polysilicon.

According to still yet another embodiment of the present disclosure, the polysilicon is pretreated by irradiating the third microwave to the polysilicon in the polysilicon pretreatment step. Thus, the pretreatment is performed at a relatively low temperature, thereby minimizing thermal deformation of the polysilicon.

According to still yet another embodiment of the present disclosure, there is an advantage in that defects in the crystalline silicon in the entire area of the vertical NAND channel are reduced by removing defects in the crystalline silicon via high-pressure heat treatment under a hydrogen atmosphere in the defect removal step.

### BRIEF DESCRIPTION OF DRAWINGS

FIG. 1 is a cross-sectional perspective view schematically illustrating a three-dimensional NAND flash memory array according to an embodiment of the present disclosure.

FIG. 2 is an enlarged front cross-sectional view of a line A in FIG. 1.

(a) to (e) of FIGS. 3 are diagrams schematically illustrating a process of crystallizing (MILC) a vertical NAND channel according to an embodiment of the present disclosure.

FIG. 4 is a flowchart illustrating a method for manufacturing a three-dimensional NAND flash memory array according to an embodiment of the present disclosure.

### DETAILED DESCRIPTIONS

Hereinafter, preferred embodiments of the present disclosure will be described in detail with reference to the accompanying drawings. However, the technical idea of the present disclosure is not limited to the embodiments described herein and may be embodied in other forms. Rather, the embodiments disclosed herein are provided to enable the disclosed contents to be thorough and complete and to sufficiently convey the idea of the present disclosure to those skilled in the art.

In this specification, when a first component is referred to as being on a second component, it means that the first component may be formed directly on the second component or a third component may be interposed therebetween. In addition, in the drawings, the shape and size are exaggerated for the effective description of the technical content.

In addition, in various embodiments of the present disclosure, terms such as first, second, third, and the like have been used to describe various components, but these components should not be limited by these terms. These terms are only used to distinguish one component from another component. Therefore, what is referred to as the first component in one embodiment may be referred to as the second component in another embodiment. Each embodiment as described and illustrated herein also includes a complementary embodiment thereto. In addition, in the present specification, ‘and/or’ is used as a meaning including at least one of components listed before and after ‘and/or’.

As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. It will be understood that when a first element or layer is referred to as being “connected to”, or “coupled to” a second element or layer, the first element may be directly connected to or coupled to the second element or layer, or one or more intervening elements or layers may be present therebetween.

In addition, in the following description of the present disclosure, when it is determined that a detailed description of a known function or configuration related thereto may unnecessarily obscure the gist of the present disclosure, the detailed description thereof will be omitted.

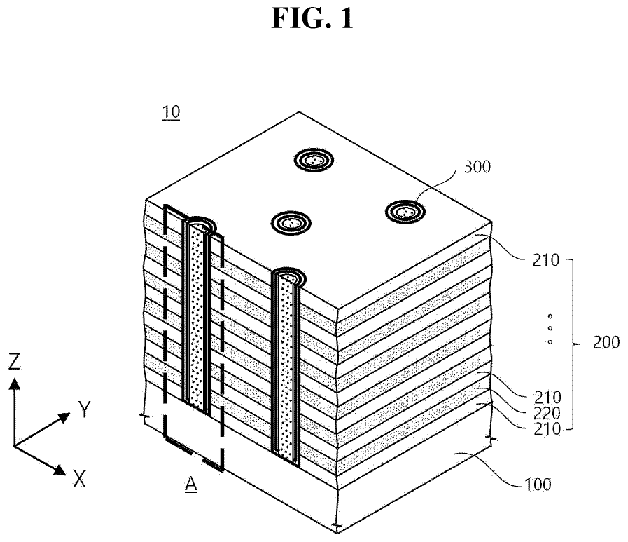

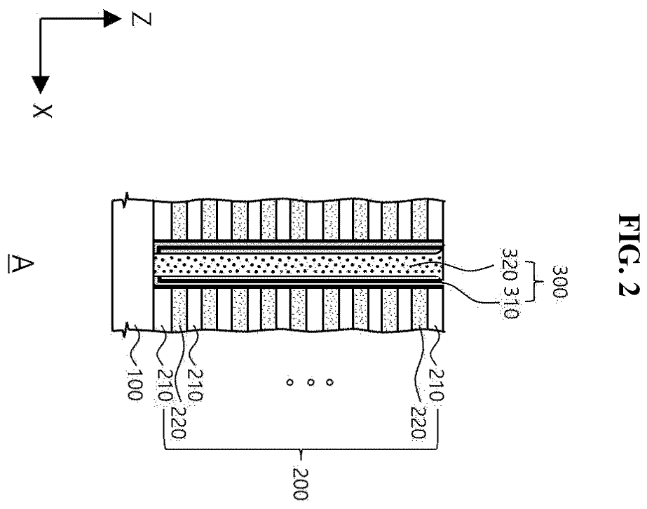

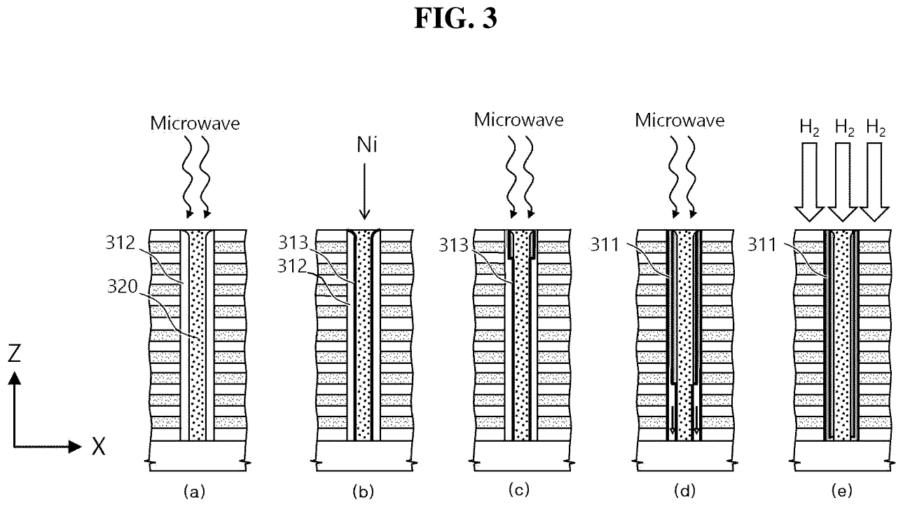

FIG. 1 is a cross-sectional perspective view schematically illustrating a three-dimensional NAND flash memory array 10 according to an embodiment of the present disclosure, and FIG. 2 is an enlarged cross-sectional view of A in FIG. 1.

The 3D NAND flash memory array 10 according to an embodiment of the present disclosure may include a vertical NAND channel 300.

Referring to FIGS. 1 and 2, the vertical NAND channel 300 may vertically extend in a Z-axis direction on the XYZ cartesian coordinate system while being disposed on a substrate 100. The vertical NAND channel 300 may be a path through which a carrier such as a hole or an electron flows.

The vertical NAND channel 300 may include polysilicon 310 and an oxide film 320. The vertical NAND channel 300 may have a macaroni structure in which the polysilicon 310 constitutes a body and an inside of the body is filled with the oxide film 320. That is, the oxide film 320 may be buried in an inner space defined by the polysilicon 310.

Since the vertical NAND channel 300 has a macaroni structure, a thickness of a cross-section (cross-section on a X-Y plane) of the vertical NAND channel 300 may be reduced. When the thickness of the cross-section of the vertical NAND channel 300 decreases, the leakage current (Off Current Leakage Current or Subthreshold Leakage Current) may decrease and the swing characteristics (SS: subthreshold swing) may be improved.

On the X-Y plane of FIG. 1, the polysilicon 310 may have a ring-shaped cross-section in which the oxide film 320 is present in an inner space defined by the polysilicon 310.

According to a method for manufacturing a 3D NAND flash memory array to be described later, the amorphous silicon 312 constituting the polysilicon 310 may be crystallized to be converted into crystalline silicon 311.

Referring back to FIGS. 1 and 2, the substrate 100 may have a main surface of a horizontal surface. The horizontal plane may face the XY plane.

A polygate 200 may include a plurality of multi-layered gates 210 and a plurality of multi-layered gate insulating layers 220 that are alternately stacked on top of each other. The polygate 200 may face the substrate 100 and have a horizontal surface. The polygate 200 may surround at least a portion of the vertical NAND channel 300.

The gate insulating layer 220 may be provided between the adjacent gates 210. The gate insulating layers 220 and the gates 210 may be alternately stacked on top of each other.

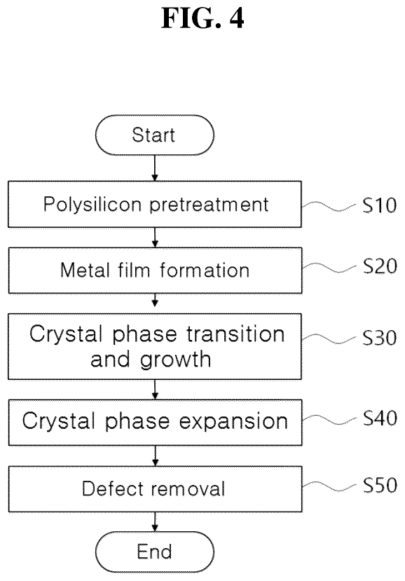

(a) to (e) in FIG. 3 are diagrams schematically illustrating a crystallization (MILC) process of a vertical NAND channel according to an embodiment of the present disclosure, and FIG. 4 is a flowchart illustrating a method for manufacturing a three-dimensional NAND flash memory array according to an embodiment of the present disclosure.

Hereinafter, a method for manufacturing a three-dimensional NAND flash memory array according to an embodiment of the present disclosure will be described in detail in a time series manner.

Referring to (a) to (e) of FIG. 3 and FIG. 4, a method for manufacturing a three-dimensional NAND flash memory array may include a metal film forming step S20, a crystal phase transition and growth step S30, and a crystal phase expansion step S40. In another embodiment, the method for manufacturing a three-dimensional NAND flash memory array may further include a polysilicon pretreatment step S10 and a defect removal step S50.

In the polygate forming step (not shown), a polygate may be formed by alternately stacking the gates and the gate insulating layer on a substrate.

In an opening forming step (not shown), an opening may be formed to form a vertical NAND channel. The opening may correspond to an area in which the polysilicon to be described later is to be formed. In the opening forming step (not shown), at least one opening may be formed in any area of the polygate.

In the polysilicon forming step (not shown), the polysilicon may be formed by depositing silicon (Si) and an oxide filler into the opening. More specifically, in the polysilicon forming step (not shown), silicon (Si) may be deposited into in the opening so as to have a predetermined thickness and then an oxide filler may be sequentially filled into a hollow portion inside the deposited silicon (Si).

The oxide filler may be an insulating material such as silicon oxide (SiₓO_{y} where each of x and y is a positive integer). For example, the oxide filler may be made of SiO₂.

In the polysilicon forming step (not shown), silicon (Si) and an oxide filler are deposited, so that a ring-shaped polysilicon surrounding the oxide film may be formed in the opening so as to vertically extend. The polysilicon formed in the polysilicon forming step (not shown) may be amorphous silicon (a-Si). The oxide film may be provided to reduce the thickness of the polysilicon. The oxide film may be an insulating material such as silicon oxide (SiₓO_{y} where each of x and y is a positive integer). For example, the oxide film may be made of SiO₂.

Referring to (a) in FIG. 3 and FIG. 4, in the polysilicon pretreatment step S10, polysilicon (amorphous silicon) may be pretreated. In the polysilicon pretreatment step S10, third microwave may be irradiated thereto to remove incomplete bonds such as SiOH, non-binding molecules, dangling bond, oxygen vacancies, and the like on polysilicon (amorphous silicon).

In the polysilicon pretreatment step S10, polysilicon (amorphous silicon) may be pretreated before forming a metal film (see 313 of (b) in FIG. 3) in the metal film forming step S20 to be described later. The fluidity of carriers in polysilicon (amorphous silicon) may be improved due to the polysilicon pretreatment step S10.

In the polysilicon pretreatment step S10, the third microwave may be locally irradiated to an end of the vertical NAND channel. More specifically, in the polysilicon pretreatment step S10, the ohmic conduction absorption may be induced in the polysilicon by injecting electromagnetic wave energy resulting from the third microwave irradiation into the polysilicon (amorphous silicon).

The polysilicon pretreatment step S10 may be performed in a temperature range of 200° C. to 600° C.

The third microwave according to an embodiment may have an output value of 1 KW to 10 KW, preferably an output value of 4 KW.

The third microwave according to an embodiment may have a frequency band of 2.4 GHz to 2.5 GHz, preferably a frequency band of 2.45 GHz. In addition, the third microwave according to another embodiment may have a frequency band of 5.8 GHz to 5.9 GHZ, preferably a frequency band of 5.85 GHz.

Referring to (b) in FIG. 3 and FIG. 4, in the metal film forming step S20, the metal film 313 may be formed by injecting metal into an upper end area of the vertical NAND channel. In the metal film forming step S20, a thin-film metal film may be formed along a sidewall of the polysilicon (amorphous silicon) constituting the vertical NAND channel. The metal film may be formed in a form of a film between polysilicon (amorphous silicon) and the oxide film.

In the metal film forming step S20 according to an embodiment, the injection of the metal atoms into the vertical NAND channel may be accelerated by applying an external electric field thereto.

According to an embodiment, the metal constituting the metal layer 313 may be any one selected from nickel (Ni), titanium (Ti), molybdenum (Mo), cobalt (Co), and aluminum (Al). According to an embodiment, when nickel (Ni) is injected, the crystal structure of the vertical NAND channel may be densified after the crystallization. Although it is assumed in (b) in FIG. 3 that nickel (Ni) is injected, this is merely an example, and the type of the metal is not limited thereto.

Referring to (c) in FIG. 3 and FIG, 4, in the crystal phase transition and growth step S30, crystalline silicon may be grown in the upper end area of the vertical NAND channel. In the crystal phase transition and growth step S30, the metal and the polysilicon (amorphous silicon) may bind to each other to form crystalline silicon. In the crystal phase transition and growth step S30, polysilicon (amorphous silicon) located in the upper end area of the vertical NAND channel starts to be crystallized into crystalline silicon at an interface between the polysilicon (amorphous silicon) and the metal film. In the crystal phase transition and growth step S30, crystallized silicon may be grown in the Z-direction, i.e., inwardly of the polysilicon, at the interface of the polysilicon of the vertical NAND channel end area. In the crystal phase transition and growth step S30, first microwave may be irradiated. When the first microwave is irradiated, a metal atom and a silicon (Si) atom may bind to each other to form crystalline silicon. According to an embodiment, when the metal is nickel (Ni), the crystalline silicon may be nickel silicide (NiSi₂).

In the crystal phase transition and growth step S30, the first microwave may be locally irradiated to an end portion of the vertical NAND channel. More specifically, in the crystal phase transition and growth step S30, the ohmic conduction absorption may be induced by injecting electromagnetic wave energy resulting from the first microwave irradiation into the metal film, such that the speed at which the metal atoms in the metal film penetrate into the polysilicon at the interface between the metal film and the polysilicon may be accelerated.

In another embodiment, in the crystal phase transition and growth step S30, the crystalline silicon may be grown by applying heat to the three-dimensional NAND flash memory array. For example, the heat may be applied to the three-dimensional NAND flash memory array for 720 minutes, such that the crystalline silicon may be grown. Preferably, the crystalline silicon may be grown by applying the heat to the three-dimensional NAND flash memory array for 30 to 120 minutes.

When the crystal phase transition and growth step S30 is performed at a low temperature, damage to polysilicon and the metal film may be minimized. When heat of about 700° C. is applied to the 3D NAND flash memory array in the crystal phase transition and growth step S30, a high heat load may be caused. In order to reduce the heat load, in the crystal phase transition and growth step S30, the first microwave may be irradiated to the three-dimensional NAND flash memory array in a temperature range of 200° C. to 600° C. In the crystal phase transition and growth step S30, the first microwave may have an output value of 1 KW to 10 KW, preferably an output value of 4 KW.

In the crystal phase transition and growth step S30, the first microwave may have a frequency band of 2.4 GHz to 2.5 GHz, preferably a frequency band of 2.45 GHz. In addition, the first microwave according to another embodiment may have a frequency band of 5.8 GHz to 5.9 GHz, preferably a frequency band of 5.85 GHz.

Referring to (d) in FIG. 3 and FIG. 4, in the crystal phase expansion step S40, the crystalline silicon may be expanded to the bottom surface of the vertical NAND channel having a predetermined thickness by irradiating second microwave to the end of the vertical NAND channel. In the crystal phase expansion step S40, polysilicon may react with the metal so as to be crystallized into the crystalline silicon up to the bottom surface of the vertical NAND channel. In the crystal phase expansion step S40, the second microwave may be irradiated toward the bottom surface of the vertical NAND channel in the Z-direction. In the crystal phase expansion step S40, the second microwave may be irradiated to provide kinetic energy to expand the crystalline silicon to the bottom surface of the vertical NAND channel.

In the crystal phase expansion step S40, the second microwave may be irradiated such that the crystalline silicon may be expanded to a bottom layer of the vertical NAND channel in a relatively short time.

More specifically, in the crystal phase expansion step S40, the kinetic energy in the form of electromagnetic waves of the second microwave may be applied to the crystalline silicon such that the crystalline silicon may be expanded to the entire area of the vertical NAND channel.

The process of irradiating the second microwave in the crystal phase expansion step S40 may be performed for a relatively shorter process time, compared to a process time in a scheme of applying heat to the three-dimensional NAND flash memory array.

In an embodiment, 500° C. of heat may be applied to the three-dimensional NAND flash memory array for 720 minutes to expand the crystalline silicon. When the 3D NAND flash memory array is exposed to a high temperature for a long time, a high heat load of the vertical NAND channel may be caused.

Therefore, in order to minimize damage to the polysilicon and the metal, the crystal phase expansion step S40 may be performed in a temperature range of 200° C. to 400° C.

Preferably, the crystal phase expansion step S40 may be performed for 30 minutes to 120 minutes.

In this case, the second microwave may have an output value of 1 KW to 10 KW, preferably an output value of 4 KW. In the crystal phase expansion step S40, the second microwave may be locally irradiated to an end portion of the vertical NAND channel.

The second microwave WM according to an embodiment may have a frequency band of 2.4 GHz to 2.5 GHz, preferably a frequency band of 2.45 GHz. In addition, the second microwave according to another embodiment may have a frequency band of 5.8 GHz to 5.9 GHZ, preferably a frequency band of 5.85 GHz.

Referring to (e) in FIG. 3 and FIG. 4, in the defect removal step S50, the 3D NAND flash memory array may be annealed in a hydrogen atmosphere to remove defects on crystalline silicon.

When some metals constituting crystalline silicon remain as metal atoms without binding to the silicon, the remaining metal may act as a defect of the vertical NAND channel itself. In the defect removal step S50, the 3D NAND flash memory array may be annealed in a hydrogen atmosphere to remove the defect such as the metal atom in a non-binding state in crystalline silicon.

The defect removal step S50 may be performed for a relatively short time. Preferably, the defect removal step S50 may be performed for 10 to 60 minutes.

In the defect removal step S50, the annealing may be performed while 3% to 10% of hydrogen (H₂) or deuterium (D₂) is provided as a reaction gas. The gas other than the reaction gas may be nitrogen (N₂). In particular, when the concentration of hydrogen (H₂) is 10% or higher, the risk of explosion in a combustible environment may be increased. However, since the concentration of hydrogen (H₂) is 10% or higher may be used if the risk of explosion is controlled according to the design of an annealing apparatus. Thus, the use of hydrogen (H₂) or deuterium (D₂) at a concentration higher than the above concentration (e.g., 10% or higher or 100%) is not excluded. In some embodiments, the reaction gas including oxygen (O), fluorine (F), or nitrogen (N) may be provided in the defect removal step (S50).

In the defect removal step S50, the annealing may be performed in a pressure range of 2 atmospheres to 50 atmospheres, preferably in a pressure range of 2 atmospheres to 20 atmospheres.

In the defect removal step S50, the annealing may be performed in a temperature range of 200° C. to 800° C., preferably in a temperature range of 200° C. to 600° C., more preferably in a temperature range of 350° C. to 450° C.

Although the present disclosure has been described in detail using preferred embodiments, the scope of the present disclosure is not limited to specific embodiments and should be interpreted by the appended claims. In addition, those skilled in the art should understand that many variations and modifications may be made without departing from the scope of the present disclosure.

1. A method for manufacturing a three-dimensional NAND flash memory array, the method comprising:
a polygate forming step of alternately stacking gates and gate insulating on a substrate to form a polygate;
an opening forming step of forming an opening in the polygate;
a polysilicon forming step of depositing silicon and an oxide filler into the opening to form a polysilicon;
a metal film forming step of injecting metal into the polysilicon to form a metal film along a sidewall of the polysilicon;
a crystal phase transition and growth step of irradiating a first microwave to the opening to grow crystalline silicon between the metal film and the polysilicon; and
a crystal phase expansion step of irradiating a second microwave to the opening to expand the crystalline silicon toward a bottom surface of the opening.

2. The method for manufacturing the three-dimensional NAND flash memory array of claim 1, wherein the method further comprises a polysilicon pretreatment step of irradiating a third microwave to the opening to pretreat the polysilicon before the metal film forming step.

3. The method for manufacturing the three-dimensional NAND flash memory array of claim 1, wherein the method further comprises a defect removal step of performing an annealing process in a hydrogen atmosphere to remove a defect on the crystalline silicon after the crystal phase expansion step.

4. The method for manufacturing the three-dimensional NAND flash memory array of claim 3, wherein the defect removal step is performed in a pressure range of 2 atmospheres to 50 atmospheres.

5. The method for manufacturing the three-dimensional NAND flash memory array of claim 3, wherein the defect removal step is performed in a temperature range of 200° C. to 800° C.

6. The method for manufacturing the three-dimensional NAND flash memory array of claim 1, wherein the first microwave is output at a range of 1 KW to 10 KW.

7. The method for manufacturing the three-dimensional NAND flash memory array of claim 1, wherein the first microwave is irradiated in a frequency band range of 2.4 GHz to 2.5 GHz.

8. The method for manufacturing the three-dimensional NAND flash memory array of claim 1, wherein the crystal phase transition and growth step is performed in a temperature range of 200° C. to 600° C.

9. The method for manufacturing the three-dimensional NAND flash memory array of claim 1, wherein the metal is one selected from nickel (Ni), titanium (Ti), molybdenum (Mo), cobalt (Co), and aluminum (Al).
